(19) United States
(12) Patent Application Publication
(10) Pub. No.: US 2025/0083965 A1
(43) Pub. Date: Mar. 13, 2025

(54) MESOPOROUS GRAPHITIC CARBON MATERIALS AND PRODUCTION USING ELECTROCHEMICAL PROCESSES

(71) Applicant: MAPLE MATERIALS INC., Richmond, CA (US)

(72) Inventors: Kevin Yu, Berkeley, CA (US); Niklas Mundhenk, El Cerrito, CA (US); Drew L. Reid, San Rafael, CA (US)

(73) Assignee: MAPLE MATERIALS INC., Richmond, CA (US)

(21) Appl. No.: 18/824,001

(22) Filed: Sep. 4, 2024

Related U.S. Application Data
(60) Provisional application No. 63/537,883, filed on Sep. 12, 2023.

(51) Int. Cl. C01B 32/205; C01B 32/21; C23C 16/24; C23C 16/44; C25B 1/135

(52) U.S. Cl. CPC C01B 32/205; C01B 32/21; C23C 16/24; C23C 16/4417; C25B 1/135; C01P 2002/72; C01P 2002/82; C01P 2004/03; C01P 2006/14; C01P 2006/17

(57) ABSTRACT

A graphitic carbon material includes a plurality of carbon particles having a generally spherical shape and a mesoporous structure. Each carbon particle includes a plurality of graphite sheets configured as generally hexagonally shaped cells connected to one another in a 3-D honeycomb-like structure of multiple cell arrays having a plurality of pores separating the cell arrays. An electrochemical process for producing the graphitic carbon material includes the steps of: providing a molten carbonate; dissociating the molten carbonate into a plurality of carbonate ions; electro-catalytically reducing the carbonate ions to produce a graphitic carbon material comprised of a plurality of carbon particles, along with at least three oxide anions and a metal oxide ion.

### CROSS REFERENCE TO RELATED APPLICATION

This application claims priority from U.S. Provisional No. 63/537,883, filed Sep. 12, 2023, which is incorporated herein by reference.

### FIELD

This disclosure relates to graphitic carbon materials and to processes for making graphitic carbon materials.

### BACKGROUND

Graphite includes carbon atoms in a crystalline lattice structure. Graphite has unique characteristics, such as a high melting point, a high thermal conductivity and a high electrical conductivity. These characteristics allow graphite to be used in a variety of applications. For example, graphite is an important material in components and systems that play a critical role in the non-carbon energy transition from fossil fuels to electricity, wind and thermal energy. As a specific example, graphite can be used in the fabrication of lithium-ion batteries, as an anode material. One problem with prior art processes, it that graphite is typically produced from fossil fuels which produce a significant amount of CO₂ emission as a by product. It would be desirable to be able to produce graphite using non-solid carbon raw materials and with less greenhouse gas emissions to the environment.

The present disclosure is directed to graphitic carbon materials having a novel geometry and characteristics. The present disclosure also relates to processes for making the graphitic carbon materials with a quality and in a quantity sufficient for large scale manufacturing applications and without the production of harmful by-products. An exemplary process uses electricity to split carbonates into graphite and oxygen, and is faster, cleaner, and lower in cost than prior art processes. In addition, the graphitic carbon materials produced by the process are in powder form, which provides materials for use in additive manufacturing and powder metallurgy.

### SUMMARY

A graphitic carbon material includes a plurality of carbon particles having a generally spherical shape and a mesoporous structure. Each carbon particle comprises a plurality of graphite sheets configured as generally hexagonally shaped cells interconnected to one another in a 3-D honeycomb-like structure of multiple cell arrays having a plurality of pores separating the cell arrays. In illustrative embodiments, the graphitic carbon material has a carbon content of about 85-100% and a high porosity, with each graphite sheet having a thickness of only about 50 nanometers or less. In addition, the interconnected hexagonally shaped cells form an electrical network that provides low electrical resistivities throughout the carbon particles. Other characteristics of the carbon particles include: density, surface area, expansion and pH selected to make the graphitic carbon material suitable for various non-carbon energy applications, such as anodes for batteries, using a suitable manufacturing process, such as additive manufacturing or powder metallurgy.

In an exemplary embodiment, a graphitic carbon anode material includes the carbon particles and a graphitized carbon coating formed on outer surfaces of the carbon particles. The graphitized carbon coating increases the density of the carbon particles and minimizes the particle surface area. In another exemplary embodiment, a composite graphitic carbon anode material includes silicon deposited into pores of the carbon particles.

An electrochemical process for producing the graphitic carbon material includes the steps of: providing a molten carbonate; dissociating the molten carbonate into a plurality of carbonate ions; electrocatalytically reducing the carbonate ions to produce a graphitic carbon material comprised of a plurality of carbon particles, along with at least three oxide anions and a metal oxide ion; reacting one oxide anion with two adjacent metal oxide ions to produce a metal oxide; and combining two remaining oxide anions in an oxidation reaction that results in a four-electron transfer and evolution of oxygen gas. The process can also include the steps of coating the carbon particles with a graphitization carbon layer, then calcinating, graphitizing and classifying the coated carbon particles into a desired particle size distribution.

For making a composite graphitic carbon anode material having embedded silicon, the process can also include the step of chemically vapor depositing (CVD) silicon into pores of the carbon particles.

### BRIEF DESCRIPTION OF THE DRAWINGS

FIG. 1A is a scanning electron micrograph having a scale bar of 100 μm on the left side of a graphitic carbon material comprised of a plurality of carbon particles;

FIG. 1B is a scanning electron micrograph having a scale bar of 60 μm on the left side of an enlarged portion of a single carbon particle of the graphitic carbon material comprised of graphite sheets formed as a plurality of arrays in a 3-D honeycomb structure;

FIG. 1C is a scanning electron micrograph having a scale bar of 20 μm on the left side of an enlarged portion of the carbon particle;

FIG. 1D is a scanning electron micrograph having a scale bar of 8 μm on the left side of an enlarged portion of the carbon particle;

FIG. 2A is a scanning electron micrograph having a scale bar of 4 μm on the left side of an enlarged portion of the carbon particle;

FIG. 2B is an enlarged schematic perspective view having a scale bar of 0.8 μm on the left side of an enlarged portion of the carbon particle;

FIG. 3 is a graph illustrating pore size in nm on the x-axis versus dV/dW pore volume (cm²/g: nm) on the y-axis for three samples of the graphitic carbon material;

FIG. 4 is a bar graph illustrating total pore volume (cm³/g) (2-6 nm) on the y-axis for the three samples of the graphitic carbon material;

FIG. 5 is an x-ray diffractogram for the graphitic carbon material;

FIG. 6 is a Raman spectrum for the graphitic carbon material with Raman Shift (cm⁻¹) on the x-axis and Normalized Intensity (a.u.) on the y-axis;

FIG. 7 is schematic diagram illustrating a system and a process for producing the graphitic carbon material;

FIG. 8 is a flow chart illustrating steps in a process for producing the graphitic carbon material;

FIG. 9 is an enlarged schematic cross sectional view of a carbon particle having a graphitized carbon coating;

FIG. 10A is an enlarged schematic cross sectional view of a composite graphitic carbon anode material having embedded silicon;

FIG. 10B is an enlarged schematic cross sectional view of a carbon particle of the composite graphitic carbon anode material having a graphitized silicon carbon coating;

FIG. 11 is an enlarged schematic perspective view of an anode constructed using the graphitic carbon anode material; and

FIG. 12 is a schematic perspective view illustrating different applications for the graphitic carbon material for constructing batteries for providing non-carbon energy.

### DETAILED DESCRIPTION

As used herein, the term “mesoporous” means porous materials having pore diameters between 2 and 50 nm, high specific surface area, regular and orderly pore structure, and narrow pore size distribution. “Graphite” means the crystalline form of the element carbon. The term “graphite sheets” means flat planar sheets having a thickness of about 50 nm or less and a selected geometry. The term “geometry” when referring to the graphite sheets means the shape and size of the sheets. The term “honeycomb structure” when referring to the graphite sheets means a structure formed by the graphite sheets having the geometry of a honeycomb comprised of interlocking generally hexagonally shaped cells. “Carbonate” means a salt of carbonic acid, H₂CO₃, characterized by the presence of the carbonate ion, a polyatomic ion with the formula CO2-3. “Alkali metal carbonate” means a carbonate containing a metal.

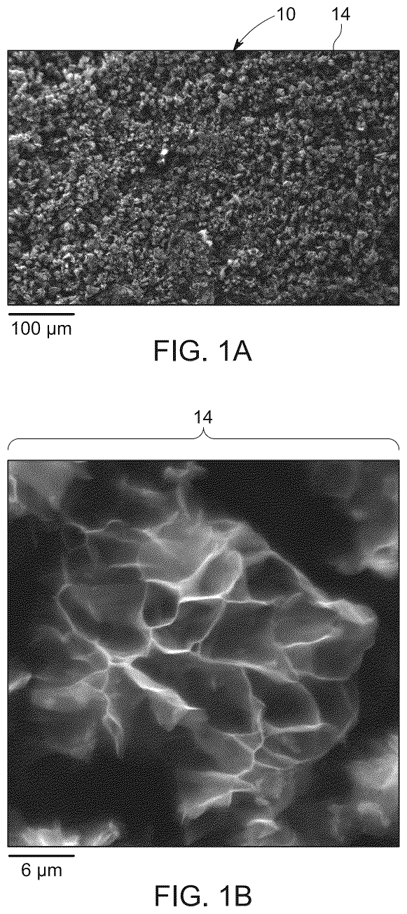

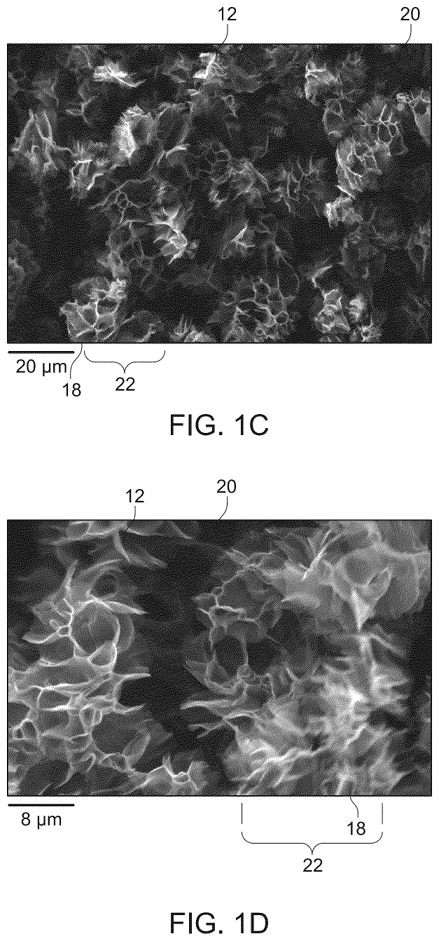

Referring to FIG. 1A, a graphitic carbon material 10 is shown. The graphitic carbon material 10 includes a plurality of carbon particles 14 having a generally spherical shape and a mesoporous structure. Although the carbon particle 14 is described herein as having a generally spherical shape, it is understood that in actual practice the carbon particle 14 can also be more asymmetrical and organically shaped. FIG. 1B illustrates an enlarged portion of a single carbon particle 14. FIG. 1A has a scale of 100 μm per 0.5 inches and FIG. 1B has a scale of 6 um per 0.5 inches. Each carbon particle 14 has a diameter D of between 5 to 200 μm. In addition, the graphitic carbon material 10 can have a particle size distribution consisting of various particle diameters D selected to allow the graphitic carbon material 10 to be used as a material in a particular manufacturing process, such as an additive manufacturing process. Representative additive manufacturing processes include laser powder bed fusion (LPBF), laser metal deposition (LMD), electron beam deposition (EBM), binder jet 3D printing, and fused filament fabrication (FFF). As another alternative, the graphitic carbon material 10 can be configured for use in a powder metallurgy manufacturing process, which can comprise compacting the graphitic carbon material 10 in a die and then sintering or heating the resultant shape in a controlled atmosphere.

Table 1 lists exemplary physical properties for the graphitic carbon material 10 for making an anode for a battery.

TABLE 1
PHYSICAL PROPERTIES OF GRAPHITIC
CARBON MATERIAL 10
Particle Size Distribution (μm).

| | |
|---|---|
| D10 | 5-20 |
| D50 | 9-35 |
| D90 | 13-70 |
| Tapped Density (g/cm³) | >0.5 |
| BET Surface Area (m²/g) | <5 |

Table 2 lists exemplary electrochemical properties for the graphitic carbon material 10 for making an anode for a battery.

TABLE 2
ELECTROCHEMICAL PROPERTIES OF
GRAPHITIC CARBON MATERIAL 10

| | |
|---|---|
| C/10 Reversible Capacity (mAh/g) | ≥320 |
| 5 C Power Retention (%) | ≥75 |
| First Cycle Efficiency (%) | ≥90 |

Referring to FIGS. 1C and 1D, further geometry of an enlarged portion of the carbon particle 14 is shown in scanning electron micrographs. FIG. 1C has a scale of 20 μm per 0.5 inches and FIG. 1D has a scale of 8 μm per 0.5 inches. As shown in FIGS. 1C and 1D, each carbon particle comprises a plurality of graphite sheets 12. In FIGS. 1C and 1D, the graphite sheets 12 are the light areas. As also shown in FIGS. 1C and 1D, the graphite sheets 12 are configured as multiple arrays 22 comprised of generally hexagonally shaped cells 18 connected to one another in a 3-D honeycomb-like structure and separated by a plurality of pores 20. In FIGS. 1C and 1D, the pores are the dark areas. The pores have a pore size of between 2 to 100 nm.

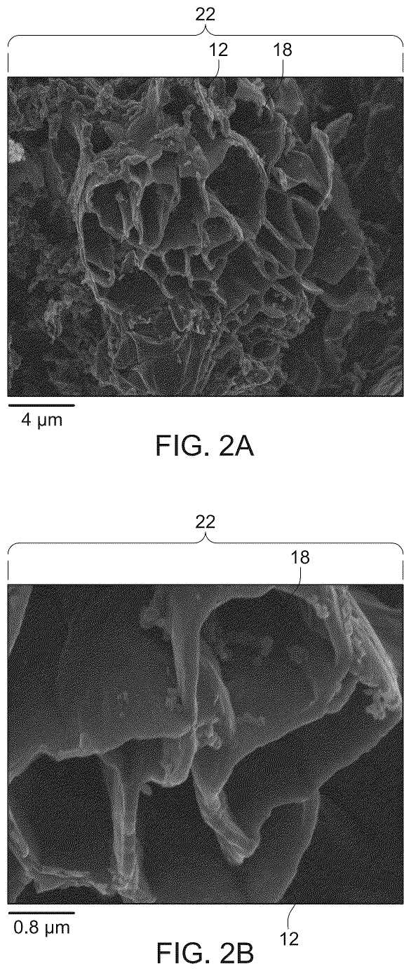

Referring to FIGS. 2A and 2B, the geometry of the hexagonally shaped cells 18 and the graphite sheets 12 are illustrated. FIG. 2A has a scale of 40 μm per 0.5 inches and FIG. 2B has a scale of 0.8 μm per 0.5 inches. In FIG. 2A the array 22 comprises a plurality of hexagonally shaped cells 18 connected to one another. In addition, the graphite sheets 12 that form the cells 18 have a thickness of T of only about 50 nanometers. Further, the interconnected hexagonally shaped cells 18 formed by the graphite sheets 12 form an electrical network that provides a low electrical resistivity throughout the carbon particle 14. Although the hexagonally shaped cells 18 are described herein as being uniform symmetrical structures, it is understood that in actual practice, the arrays 22 and hexagonally shaped cells 18 as well, have a more organic structure with curves and missing parts of the hexagons, substantially as shown in the scanning electron micrographs of FIGS. 2A and 2B. FIG. 2B illustrates the 3-D honeycomb-like structure with the hexagonally shaped cells 18 having a height H and the arrays 22 having a length L.

In illustrative embodiments, the graphitic carbon material 10 has a carbon content of 85-100% and a high porosity. Other characteristics of the graphitic carbon material 10 include: density, surface area, expansion and pH configured to make the graphitic carbon material 10 suitable for various non-carbon energy applications, such as anodes for batteries. Table 3 lists exemplary physical properties of the graphitic carbon material 10 for making an anode for a battery. Table 4 lists exemplary crystalline properties of the graphitic carbon material 10 for making an anode for a battery.

TABLE 3
PHYSICAL PROPERTIES OF GRAPHITIC
CARBON MATERIAL 10

| | |
|---|---|
| % Carbon | 85-100 |
| % Sulfur | 0-0.01 |
| **Electrical Resistivity (Ω · Cm) | <0.06 |
| True Density (g/cc) | 2.12-2.26 |
| Tapped Density (g/cc) | 0.1-1.0 |
| Surface Area (m/g) | 1-15 |
| Low Pressure Density (g/cc, 6,500 psi) | 1.1-1.3 |
| High Pressure Density (g/cc, 32,000 psi) | 1.7-2 |
| % Expansion (10 grams @ 6,500 psi) | 70-100 |
| pH | 7.8-10.2 |

PARTICLE SIZE DISTRIBUTION (μm)

| | |
|---|---|
| D10 | 5-15 |
| D50 | 15-60 |
| D90 | 60-200 |

TABLE 4
CRYSTALLINE PROPERTIES OF GRAPHITIC
CARBON MATERIAL 10

| | | |
|---|---|---|
| d-spacing | 0.3354-0.3440 | nm |
| Lc(002→110) Crystallite Size | 2-10 | nm |

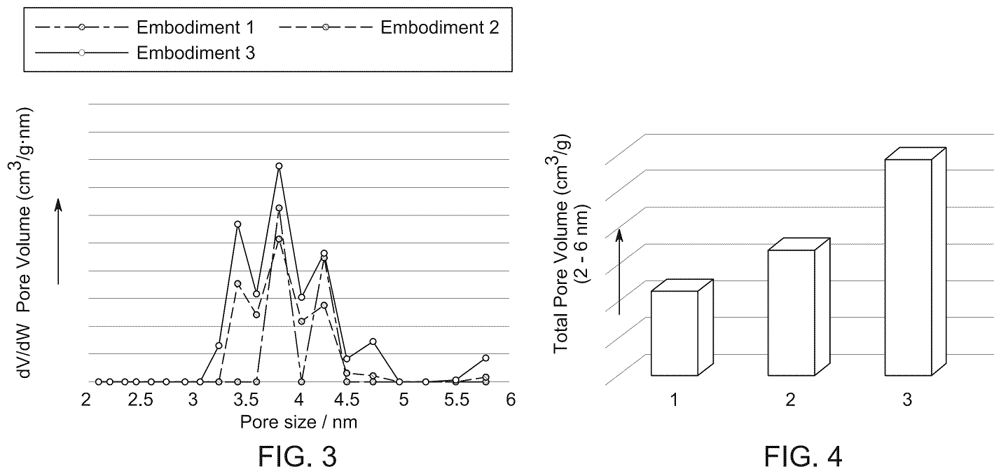

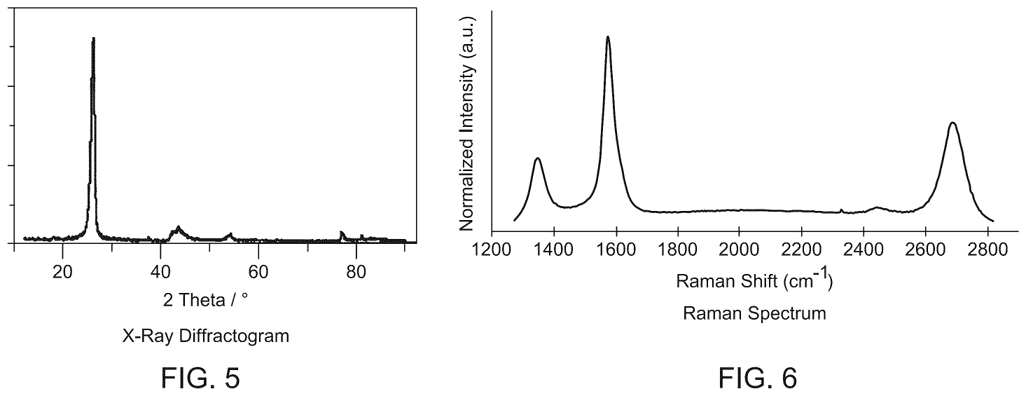

FIGS. 3 and 4 illustrate mesoporosity characteristics of the graphitic carbon material 10. FIGS. 5 and 6 illustrate x-ray diffractogram and Raman spectrum characteristics of the graphitic carbon material 10.

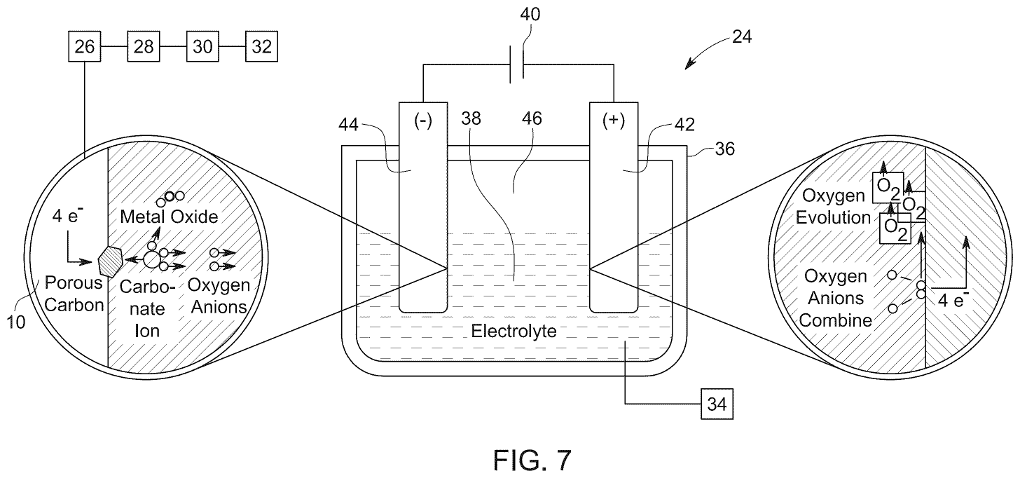

Referring to FIG. 7, a system 24 for producing the graphitic carbon material 10 using an electrochemical process is illustrated. The system 24 includes an electrochemical apparatus 36 configured to perform an electrochemical process to break down an electrolyte 38 to produce the graphitic carbon material 10. The electrochemical apparatus 36 includes a sealed reactor chamber 46 configured to contain the electrolyte 38 in molten form. The electrochemical apparatus 36 also includes an energy source 40 electrically connected to an electrochemical anode 42 and to an electrochemical cathode 44 configured to produce an electric current to drive the chemical reactions shown in the bubbles on the left and the right side of FIG. 7. The electrochemical anode 42 and the electrochemical cathode 44 are located within the reactor chamber 46 and are at least partially submerged in the electrolyte 38. The graphitic carbon material 10 forms on the electrochemical cathode 44 and in the electrolyte 38 circumjacent to the electrochemical cathode 44. The graphitic carbon material 10 can be removed from the electrochemical cathode 44 using a suitable process, such as vibration or scraping of the electrochemical cathode 44, either continuously or in batches. The graphitic carbon material 10 contained in the electrolyte 38 can be removed by separating the solid carbon material from the liquid electrolyte 38 using a liquid-solid separator either continuously or in batches. Other by-products can be removed from the reactor chamber 46 using suitable mechanisms such as vents for gaseous by-products and separator mechanisms for solid by-products.

Still referring to FIG. 7, the electrolyte 38 can comprise a molten carbonate. A preferred carbonate comprises an alkali carbonate. Other suitable carbonates include lithium carbonate, sodium carbonate, potassium carbonate and mixtures thereof. The electrochemical apparatus 36 can also include a melting apparatus 34 such as a heating apparatus in the reactor chamber 46, or a separate melting furnace, for providing the molten carbonate which forms the electrolyte 38.

Still referring to FIG. 7, in the reactor chamber 46 several chemical reactions occur. A first chemical reaction comprises dissociating the molten carbonate into a plurality of carbonate ions. A second chemical reaction comprises electrocatalytically reducing the carbonate ions to produce the graphitic carbon material 10 comprised of the carbon particles 14 (FIG. 1A). The second chemical reaction also produces at least three oxide anions and a metal oxide ion. A third chemical reaction comprises reacting one oxide anion with two adjacent metal oxide ions to produce a metal oxide. The first, second and third chemical reactions are shown in the bubble on the left of FIG. 7. A fourth chemical reaction comprises combining two remaining oxide anions in an oxidation reaction that results in a four-electron transfer and evolution of oxygen gas. The fourth chemical reaction is shown in the bubble on the right of FIG. 7. These reactions are summarized as follows:

$${Li}_{2} {CO}_{3} \to 2 {Li}^{+} + {CO}_{3}^{2 -} \qquad ( 1 )$$

$${CO}_{3}^{2 -} + 4 {e}^{-} \to {C}_{( s )} + 3 {O}^{2 -} \qquad ( 2 )$$

$$2 {Li}^{+} + {O}^{2 -} \to {Li}_{2} {O}_{( s )} \qquad ( 3 )$$

$$2 {O}^{2 -} \to {O}_{2 ( g )} + 4 {e}^{-} \qquad ( 4 )$$

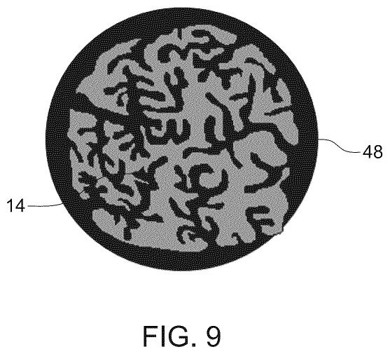

As shown in FIG. 9, for forming an anode material, the carbon particles 14 can also be coated with a graphitization carbon coating 48. As shown in FIG. 7, the system 24 can also include a coating apparatus 26 for coating the carbon particles 14 (FIG. 9) with the graphitization carbon coating 48 (FIG. 9). Suitable materials for the graphitization carbon coating 48 (FIG. 9) include graphitizable carbons, such as petroleum pitch, coal tar pitch, artificial pitch, tar or any other soft carbon graphitizable carbon. The coating apparatus 26 can comprise a spray apparatus or a tumbling apparatus configured to coat the carbon particles 14 (FIG. 9) with the graphitization carbon coating 48 (FIG. 9). The graphitized carbon coating 48 (FIG. 9) increases the density of the carbon particles 14 (FIG. 9) and minimizes the particle surface area. Minimizing the surface area reduces excessive SEI formation and improves thermal stability. The result is improved first cycle efficiency and longer cycle when used in a lithium-ion cell. Increased tapped density improves the areal energy density of an anode film when producing a lithium-ion cell.

Referring again to FIG. 7, the system 24 can also include a calcinating apparatus 28 configured to perform a calcinating process and a graphitizing apparatus 30 configured to perform a graphitizing process. The calcination and graphitization process are preferably carried out in an atmosphere in which the carbon particles 14 (FIG. 9) and the graphitization carbon coating 48 (FIG. 9) will not readily oxidize, such as a nitrogen atmosphere, an argon atmosphere, or a vacuum. The calcinating apparatus 28 is configured to perform calcination at a temperature of 400 to 2,000° C. and can include the use of a halogen gas such as fluorine or chlorine to reduce the vaporization temperatures of non-carbon constituents present in the graphitic carbon and coating material.

Still referring to FIG. 7, after calcination, the carbon particles 14 (FIG. 9) and the graphitization carbon coating 48 (FIG. 9), can be graphitized by the graphitizing apparatus 30 at a temperature of at least 2000°° C. Graphitization serves two purposes: (1) it drives off remaining impurities present in the carbon particles 14 (FIG. 9) and the graphitization carbon coating 48 (FIGS. 9), and (2) enhances the crystal structure of the carbon particles 14 (FIG. 9). This improves the d-spacing and resulting properties of an anode material such as charging and discharging capacity, electrical conductivity, and thermal conductivity. It is even better for the graphitization temperature to be 2500° C. or higher, while 2800° C. or higher yields the best crystallinity for graphite. If the graphitization temperature is under 2000°° C., the development of graphite crystals in the coating 48 (FIG. 9) will be poor, which will tend to lower the charging and discharging capacity.

Still referring to FIG. 7, the system 24 can also include a classifying apparatus configured to perform a classification process on the carbon particles 14 (FIG. 9) to achieve a target particle size distribution, tapped density, and surface area. The classifying apparatus can include screens and other mechanisms known in the art for classifying metal powders.

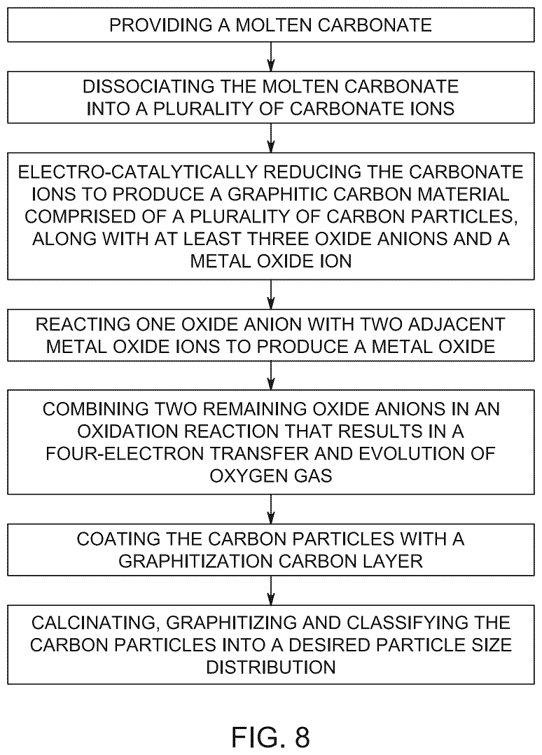

Referring to FIG. 8, steps in the process as outlined above for the system 24 are summarized.

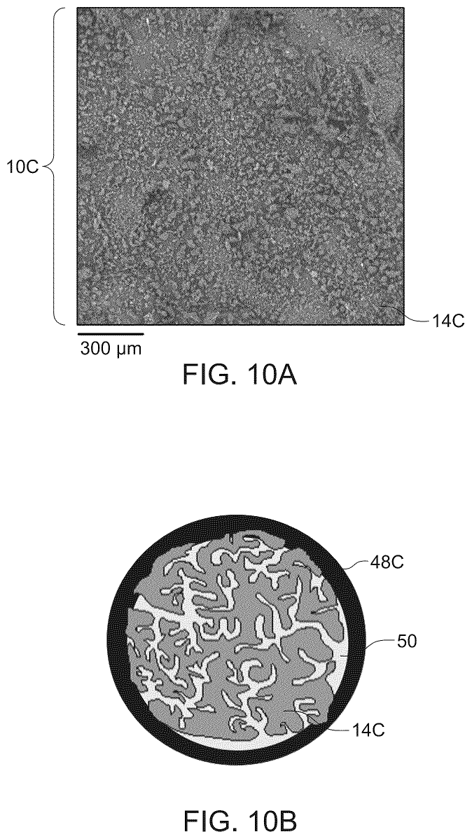

Referring to FIGS. 10A and 10B, a composite graphitic carbon anode material 10C includes a plurality of composite carbon particles 14C. As shown in FIG. 10B, each composite carbon particle 14C includes a graphitization carbon coating 48C formed on an outside surface thereof. For forming the composite carbon particles 14C, the composite carbon particle 14C can be used as a porous scaffold into which silicon 50 is deposited. As with the previous embodiment, the composite graphitic carbon anode material 10C fabrication process can include calcination, chemical vapor deposition (CVD) or chemical vapor infiltration (CVI), and classification steps. The carbon particle 14C provides the first component of the composite, and the CVD gas thermally decomposes on this solid surface to provide the second component of composite. Such a CVD approach can be employed, for instance, to create Si-C composite materials wherein the silicon is formed in the pores 20 (FIG. 1D) the carbon particles 14C. Alternatively, chemical vapor infiltration (CVI) is a process wherein a substrate (not shown) provides a porous scaffold comprising the first component of the composite, and a silicon-containing gas thermally decomposes into the porosity (into the pores) of the porous scaffold material to provide the second component of the composite. Silicon 50 is formed within the pores of the porous carbon scaffold by subjecting the porous scaffold material to a silicon containing precursor gas, preferably silane, at elevated temperatures to decompose the gas into the silicon. The silicon containing precursor gas can also be mixed with other inert gases, for example, nitrogen gas, argon gas, or the silicon deposition can occur in a vacuum atmosphere. The temperature of processing can be varied, for example the temperature can be between 200° C. and 1,000° C.

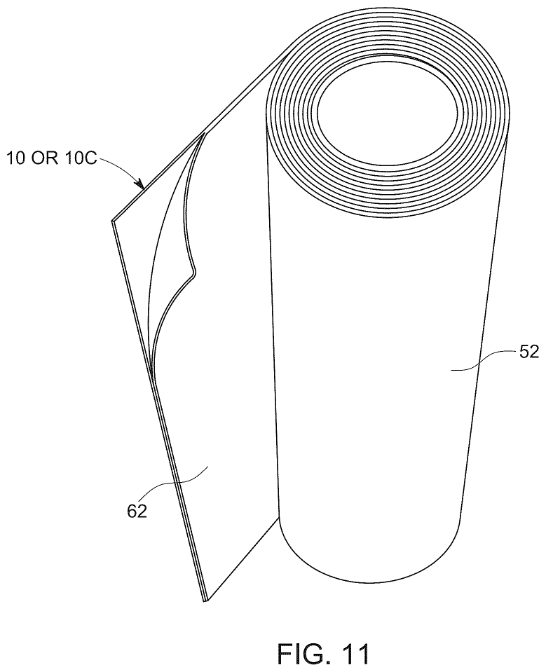

Referring to FIG. 11, an anode 52 constructed using the graphitic carbon material 10, or the composite graphitic carbon anode material 10C, is illustrated. In this example, the anode 52 comprises the graphitic carbon material 10, or the composite graphitic carbon anode material 10C, formed as sheets deposited on a metal foil 62 and rolled into a generally cylindrical shape.

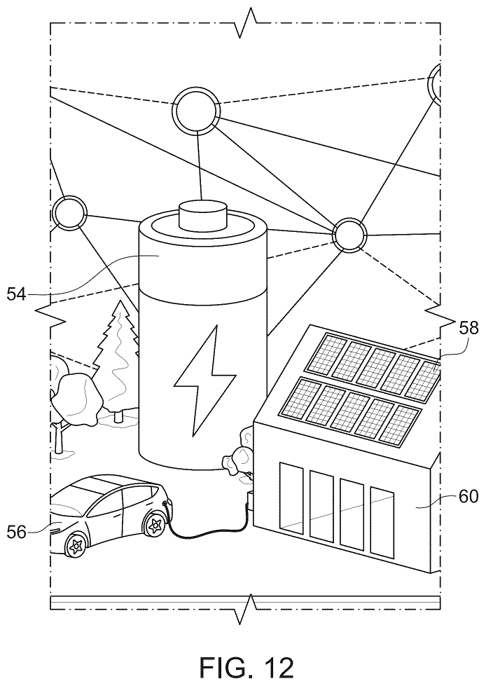

Referring to FIG. 12, the graphitic carbon material 10, or the composite graphitic carbon anode material 10C, can be used to construct batteries 54 that can be used to power electric vehicles 56 and for storing energy for solar energy systems 58 for buildings 60.

While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A graphitic carbon material comprising:
a plurality of carbon particles having a generally spherical shape and a mesoporous structure,
each carbon particle comprising a plurality of graphite sheets having a thickness of 50 nanometers or less configured as generally hexagonally shaped cells interconnected to one another in a 3-D honeycomb-like structure of multiple cell arrays having a plurality of pores separating the cell arrays.

2. The graphitic carbon material of claim 1 wherein the interconnected cells form an electrical network.

3. The graphitic carbon material of claim 1 wherein each carbon particle includes a graphitized carbon coating formed on an outside surface thereof.

4. The graphitic carbon material of claim 1 wherein each carbon particle includes a silicon graphitization carbon coating formed on an outside surface thereof comprising silicon embedded in the coating.

5. The graphitic carbon material of claim 1 wherein each carbon particle 10 has a diameter D of between 5 to 200 μm.

6. The graphitic carbon material of claim 1 wherein the pores have a pore size of between 2 to 100 nm.

7. The graphitic carbon material of claim 1 wherein each carbon particle comprises 85-100% carbon.

8. The graphitic carbon material of claim 1 wherein each carbon particle comprises 0-0.01% sulfur.

9. The graphitic carbon material of claim 1 wherein each carbon particle has an electrical resistivity of less than 0.06 ohm cm.

10. The graphitic carbon material of claim 1 wherein the material has a true density of 2.12 to 2.26 g/cc.

11. The graphitic carbon material of claim 1 wherein the material has a tapped density of 0.1-1.0 g/cc.

12. The graphitic carbon material of claim 1 wherein the material has a surface area of 1-15 m²/g.

13. The graphitic carbon material of claim 1 wherein the material has a pH of 7.8-10.2.

14. An electrochemical process for producing a graphitic carbon material comprising:
providing a molten carbonate;
dissociating the molten carbonate into a plurality of carbonate ions;
electrocatalytically reducing the carbonate ions to produce a graphitic carbon material comprised of a plurality of carbon particles, along with at least three oxide anions and a metal oxide ion;
reacting one oxide anion with two adjacent metal oxide ions to produce a metal oxide; and
combining two remaining oxide anions in an oxidation reaction that results in a four-electron transfer and evolution of oxygen gas.

15. The process of claim 14 further comprising coating the carbon particles with a graphitization carbon layer, then calcinating, graphitizing and classifying the coated carbon particles into a desired particle size distribution.

16. The process of claim 14 further comprising chemically vapor depositing (CVD) silicon into pores of the carbon particles to form a graphitized silicon carbon coating.

17. The process of claim 14 wherein the molten carbonate comprises an alkali carbonate.

18. A system for producing a graphitic carbon material comprising:
a molten carbonate;
an electrochemical apparatus configured to perform an electrochemical process to break down the molten carbonate,
the electrochemical apparatus comprising a sealed reactor chamber configured to contain the molten carbonate, an energy source electrically connected to an electrochemical anode and to an electrochemical cathode configured to produce an electric current;
the electrochemical apparatus configured to dissociate the molten carbonate into a plurality of carbonate ions, and to reduce the carbonate ions to produce a plurality of carbon particles, along with at least three oxide anions and a metal oxide ion;
the electrochemical apparatus configured to react one oxide anion with two adjacent metal oxide ions to produce a metal oxide, and to combine two remaining oxide anions in an oxidation reaction that results in a four-electron transfer and evolution of oxygen gas.

19. The system of claim 18 further comprising a calcinating apparatus configured to perform a calcinating process on the carbon particles and a graphitizing apparatus configured to perform a graphitizing process on the carbon particles.

20. The system of claim 16 further comprising a coating apparatus configured to form a graphitization carbon layer on the carbon particles.
